(19) United States
(12) Patent Application Publication
(10) Pub. No.: US 2024/0079525 A1
(43) Pub. Date: Mar. 7, 2024

(54) EFFICIENT GROUP III-NITRIDE LED DEVICES AND METHOD OF FABRICATION

(71) Applicant: The Research Foundation for the State University of New York, Albany, NY (US)

(72) Inventors: Iulian Gherasoiu, Chittenango, NY (US); Haralabos Efstathiadis, Troy, NY (US)

(21) Appl. No.: 18/140,000

(22) Filed: Apr. 27, 2023

Related U.S. Application Data
(60) Provisional application No. 63/336,461, filed on Apr. 29, 2022.

(51) Int. Cl. H01L 33/32; H01L 33/00; H01L 33/06; H01L 33/12; H01L 33/16

(52) U.S. Cl. CPC H01L 33/32; H01L 33/0075; H01L 33/06; H01L 33/12; H01L 33/16

(57) ABSTRACT

Group III-Nitride LED devices having efficient wavelength emissions across the visible light spectrum and a method for their fabrication. Templates for the epitaxial growth of these compound semiconductors on silicon and silicon substrates are provided for the selective area growth of low dislocation density crystalline Group III-Nitride alloys, such as GaN, InGaN, and the like on crystalline, lattice-mismatched substrates. The method describes the formation of the Si(x)C(y)Ge buffer layer using the deposition from sources of Ge, C and Si that enables the growth of a high crystalline quality III-Nitride layer, such as GaN, through the insertion of Si(x)C(y)Ge buffer layer at the interface between silicon and III-Nitride film.

### CROSS-REFERENCE TO RELATED APPLICATION

This application claims the benefit of U.S. Provisional Patent Application No. 63/336,461, filed Apr. 29, 2022, the entirety of which is hereby incorporated herein by this reference.

### BACKGROUND OF THE INVENTION

### 1. Field of the Invention

The present invention generally relates to semiconductor devices. More particularly, the present invention relates to templates for selective area growth of group III-nitride light-emitting diode (LED) devices and methods of forming the same.

### 2. Background of the Invention

Group III-nitrides (GaN, AlN, InN) are compound semiconductor materials with bandgap energies that can emit light spanning the range from the ultraviolet to the near infrared. These materials are used to fabricate UV, blue, or green laser diodes, high brightness light emitting diodes, microwave power transistors and power switching devices for applications in optical recording, solid state lighting, communications, radar and electric vehicles.

In fabrication, Group III-nitride thin films can be grown by metalorganic chemical vapor deposition (MOCVD), molecular beam epitaxy (MBE), or other known methods. GaN thin-films are typically grown on substrates such as sapphire silicon carbide and silicon (111), which have very different lattice constants and thermal expansion coefficients.

The III-V alloys are also an important class of semiconductors due the wide range of band gaps that can be engineered, and their propensity to emit and absorb light and their large carrier mobilities. Within the III-V alloys, the use of nitrogen (N), arsenic (As) or phosphorous (P) defines three main groups of semiconductors of nitride, arsenide and phosphide compound semiconductors.

Nitride semiconductor alloys are an important material for semiconductor device engineering due to their properties. The energy gap between the valence and the conduction bands can be tuned continuously from 6.2 eV (AlN) to 3.4 eV (GaN) and down to 0.64 eV (InN). Furthermore, the direct character of the band gap assures very efficient absorption and emission of photons with energies ranging from near infrared to deep ultraviolet. These electronic features make nitride semiconductor alloys particularly well suited for a wide range of opto-electronic devices including light emitting and laser diodes. Another feature of nitride semiconductors is their superior optical performance despite a very large density of dislocations.

Moreover, the ability to grow lattice matched semiconductor layers that are free of crystalline defects allows the fabrication of high-performance semiconductor devices with properties that surpass those from the sole use of silicon layers. For example, GaN-based high electron mobility transistors (HEMT) offer high critical electric field with low dynamic on-state resistance and smaller capacitance compared to silicon MOSFET, making GaN HEMT attractive for high power and high-speed switching that improves the overall conversion efficiency. In the field of optoelectronics, the light emitting devices (LEDs) based on GaN and its alloys with Al and In have become the dominant light sources for ambient light (white light) with electrical efficiencies of more than 80% and useful lifetimes of tens of thousands of hours, displacing incandescent and the compact fluorescent light bulbs.

However, the use of LEDs into other application areas such as ultraviolet and color displays has been less successful than blue and white LEDs. For UV-LEDs, the conversion efficiency reaches around 11-12% while for the LEDs with wavelengths longer than blue, the conversion efficiency drops precipitously forming what is known as the “green gap.” Thus, there are no efficient nitride LEDs emitting in the spectrum from green to red. This hinders the development of full color LED displays that would make use of red, green and blue (RGB) micro-LEDs fabricated using InAlGaN alloys.

The challenges that contribute to the difficulties in producing efficient LEDs that can overcome the green gap include phase segregation of InGaN alloys, lack of lattice matched substrates that generate a high density of crystal defects, the difficulty of p-type doping and the piezo- and pyro-electric polarization of the material along the c-axis causing a decrease in the spatial electron-hole overlap, and reduced recombination efficiency. Accordingly, the production of a more-efficient LED that can emit longer wavelength light which can address and overcome these challenges is needed.

### BRIEF DESCRIPTION OF THE INVENTION

The present invention is generally directed to the fabrication of LED devices that can efficiently emit light in at least the green/yellow wavelength. The LEDs are created with a template for selective area growth of group III-nitride devices, and accordingly includes a method of manufacturing an array of optoelectronic devices. The top-down method includes depositing a mask on a substrate; etching vertical trenches through the mask and a portion of the substrate to form a plurality of columnar structures, with each of the plurality of columnar structures including a top surface covered by the mask, and a plurality of side walls formed adjacent to the top surface. Alternately, using a bottom-up method, the fabrication of the columnar structures can be achieved by depositing a mask on a substrate and growing the silicon columns on the silicon substrate through the openings etched in the mask for this purpose. Then removing a portion of the side walls for each of the plurality of columnar structures to expose a section of the mask adjacent the top surface of each of the plurality of columnar structures; depositing a film: within the vertical trenches, over each of the plurality of side walls for each of the plurality of columnar structures, and over at least a portion of the mask, such that least a portion of the exposed section of the mask is uncovered by the deposited film. Then removing the mask covering the top surface of each of the plurality of columnar structures including the film deposited thereon; removing at least a portion of the film deposited over each of the plurality of sidewalls for each of the plurality of column structures adjacent to the top surface to expose an upper portion of each of the plurality of side walls; etching at least one of: the top surface of each of the plurality of columnar structures, the exposed upper portion of each of the plurality of side walls, or the film deposited over each of the plurality of sidewalls to form a pyramidal feature in each of columnar structures; and depositing a buffer layer over the pyramidal feature formed in each of the plurality of columnar structures.

Another aspect of the disclosure provides an optoelectronic device including a substrate with a plurality of columnar structures formed from the substrate, each of the plurality of columnar structures having a plurality of side walls formed adjacent to the top surface; a plurality of trenches formed adjacent to each of the plurality of columnar structures; a film disposed over the substrate and alongside the perimeter face of each columnar structure; a buffer layer disposed over each columnar structure, wherein the buffer layer is an alloy of germanium. The invention also includes a buffer layer in a semiconductor device, that has silicon ranging from 0% to 30%; carbon ranging from 0% to 10%; and germanium ranging from 60-99%.

The templates for selective area growth of group III-nitride devices and methods of fabricating them taught in the present disclosure therefore address problems associated with producing a more-efficient LED that can emit longer wavelength light.

### BRIEF DESCRIPTION OF THE DRAWINGS

FIG. 1 shows a cross-sectional view of a semiconductor device including group III-nitride material, according to embodiments of the disclosure.

FIG. 2 shows a cross-sectional view of the semiconductor device in FIG. 1 further in the build process, according to embodiments of the disclosure.

FIG. 3 is a flowchart illustrating processes for manufacturing an array of optoelectronic devices.

FIG. 4 is a flowchart extending the process of FIG. 3.

FIG. 5 is a top view of the Si substrate surface (102) after the deposition of the Ti or Cr mask pads (110).

FIG. 6 is a side cross-sectional view of the deposition of a layer of Ti or Cr after the etching of the columnar structures.

FIG. 7 a side cross-sectional view of the under-etching of the depositional layer in FIG. 6.

FIG. 8 is a side cross-sectional view of the deposition of a layer of SiO₂ on the under-etched columnar structures in FIG. 7.

FIG. 9 is a side cross-sectional view of a deposited film layer after the etching of the Ti or Cr mask in FIG. 8.

FIG. 10 is a side cross-sectional view of the formation of the pyramidal structures after the etching of the top section of the columnar structures.

FIG. 11 is a side cross-sectional view of the device of FIG. 10 with a layer of SiGeC deposited on the pyramid structure.

FIG. 12 is a side cross-sectional view of the device of FIG. 11 with a layer of InGaN deposited on the layer of SiGeC.

FIG. 13 is a side cross-sectional view of etching of a hole for a through-silicon via (TSV) and create of the negative contact anode.

FIG. 14 is a side cross-sectional view of the device of FIG. 13 with a conductive material placed into the hole to form TSV.

FIG. 15 is a side cross-sectional view of the device of FIG. 14 with a contact bump adhered to the TSV to create a negative contact electrode.

FIG. 16 is a side cross-sectional view of the device of FIG. 15, with a layer of passivating SiO₂ in the trenches.

FIG. 17 is a side cross-sectional view of the device of FIG. 16, with a conductive layer disposed on the passivating SiO₂ layer to form a positive contact electrode.

### DETAILED DESCRIPTION

As an initial matter, in order to clearly describe the current disclosure, it will become necessary to select certain terminology when referring to and describing relevant components within the disclosure. When doing this, if possible, common industry terminology will be used and employed in a manner consistent with its accepted meaning. Unless otherwise stated, such terminology should be given a broad interpretation consistent with the context of the present application and the scope of the appended claims. Those of ordinary skill in the art will appreciate that often a particular component may be referred to using several different or overlapping terms. What may be described herein as being a single part may include and be referenced in another context as consisting of multiple components. Alternatively, what may be described herein as including multiple components may be referred to elsewhere as a single part.

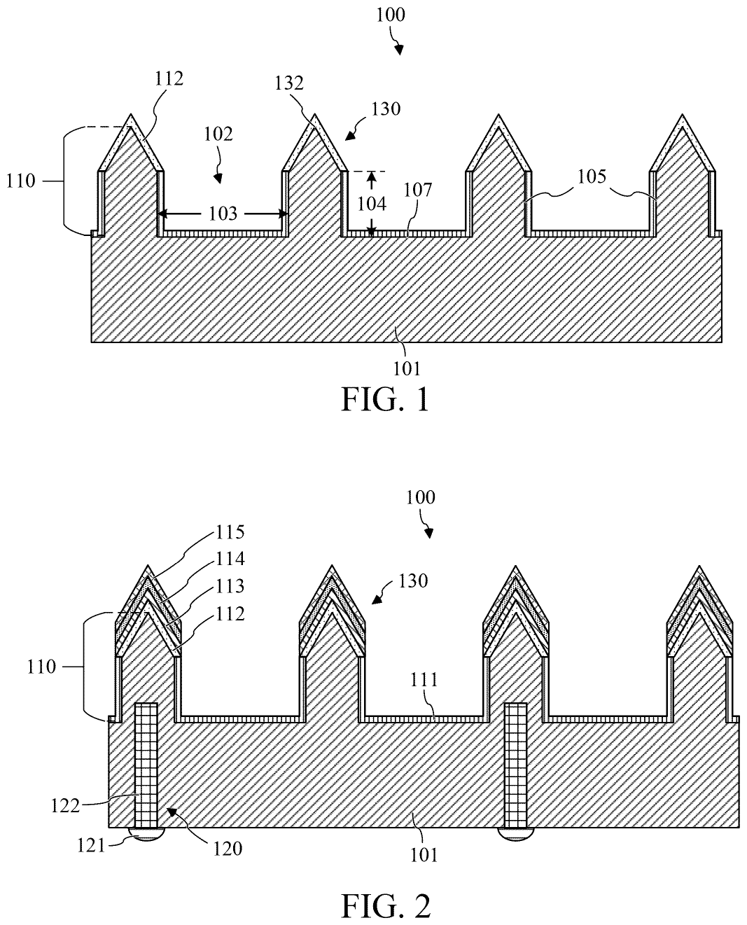

As discussed herein, the disclosure relates generally to semiconductor devices, and more particularly, to templates for selective area growth of group III-nitride devices and methods of forming the same. These and other embodiments are discussed below with reference to FIGS. 1-17. However, those skilled in the art will readily appreciate that the detailed description given herein with respect to these Figures is for explanatory purposes only and should not be construed as limiting.

FIG. 1 shows cross-sectional view of semiconductor device including group III-nitride material. Semiconductor device 100 may include a substrate 101. The substrate may include or form a base layer of semiconductor device 100 that may be formed as a semiconducting material and/or may be formed from any suitable material or material composition that includes semiconducting properties/characteristics. For example, substrate may be formed from silicon (Si), indium phosphide (InP) or gallium arsenide (GaAs). In other non-limiting examples substrate can include without limitation, substances consisting essentially of one or more compound semiconductors. Substrate can be provided as a bulk substrate or as part of a silicon-on-insulator (SOI) wafer. Additionally, or alternatively, substrate may be formed from, for example, sapphire (Al₂O₃), silicon carbide (SiC), germanium (Ge), germanium oxide (GeO), cadmium zinc telluride (CdZnTe), gallium nitride (GaN), or gallium arsenide (GaAs). Furthermore, substrate layer may be fabricated as a layer of semiconductor material, substances or materials consisting essentially of one or more compound semiconductors having a composition defined by the formula AlX1GaX2InX3AsY1PY2NY3SbY4, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substances can include II-VI compound semiconductors having a composition ZnA1CdA2SeB1TeB2, where A1, A2, B1, and B2 are relative proportions each greater than or equal to zero and A1+A2+B1+B2=1 (1 being a total mole quantity).

Semiconductor device 100 may include a plurality of trenches 102 formed therein. More specifically, a plurality of trenches 110 may be formed in and/or at least partially through a silicon substrate 101 of semiconductor device 100. In general, the processing steps described herein are specific to a silicon substrate, but other substrates and processing steps can be utilized as would be apparent to once of skill in the art. In a non-limiting example, trenches 102 may be formed in and/or at least partially through substrate 101 at a predetermined depth 104 wherein the plurality of trenches have a bottom surface 107. In a non-limiting example, predetermined depth 102 may be approximately between 1 micrometer and 5 micrometers. As a result of forming trenches 102, a plurality of columnar structures 110 may also be formed in substrate 101. That is, substrate 101 may include a plurality of columnar structures 110 having a plurality of sidewalls 105 formed and/or defined by trenches 102. Each of the plurality of columnar structures 110 of substrate 101 may be spaced and/or separated by predetermined/equidistance 103 apart. For example, each columnar structure 106 may be separated by a distance having a range between 1 micrometer and 5 micrometers. As discussed herein, the plurality of columnar structures 110 may be formed using any suitable material process or technique including, but not limited to, etching processes, polishing processes, lithographic processes, or similar. Preferably, the substrate 101 will be etched anisotropically through a metallic mask such as, but not limited to, titanium, chromium, or similar, to define the plurality of columnar structures 110. Columnar structures 110 further include a plurality of sidewalls 105 and pyramidal structure 130. Pyramidal structure 130 includes tip 132.

It should be noted that pyramidal structure 130 is generally pyramidal and not necessarily exactly so in a literal geometrical sense. In other words, the formed structure is at a minimum generally tapering to a tip 132.

Trenches 102 of substrate 101 include film 111 (FIG. 2). Specifically, film 111 is deposited or otherwise disposed upon the exposed surfaces of trenches 102 and sidewalls 105 of columnar structures 110. As discussed herein, film 111 is deposited using any suitable technique including, but not limited to, plasma-enhanced chemical vapor deposition (PECVD). Film 111 may be deposited through the same metallic mask used to define the columnar structures 110.

Buffer layer 112 is disposed over each of the plurality of columnar structures 110. Specifically, buffer layer 112 is disposed directly over pyramidal feature 130 including tip 132. Furthermore, buffer layer 112 may be fabricated as a layer of semiconductor material, substances or materials consisting essentially of one or more compound semiconductors having a composition defined by the formula SiX1GeX2CX3, where X1, X2, and X3, represent relative proportions, each greater than or equal to zero and X1+X2+X3=1 (1 being the total relative mole quantity). Preferably, the amount each material present within buffer layer 112 is on the order of 0% to 30% silicon (X1), 60% to 99% germanium (X2), and 0% to 10% carbon (X3).

In one embodiment of the buffer layer, carbon ranges from 1% to 7%, and germanium ranges from 93% to 99%. In a further embodiment, silicon ranges from 1% to 30%, and germanium ranges from 70% to 99%. Alternately, the buffer layer can be embodied with silicon ranging from 1% to 5%, carbon ranging from 1%-7%, and germanium ranging from 88% to 98%.

FIG. 2 shows a cross-sectional view of semiconductor device 100. More specifically, FIG. 1 shows semiconductor device 100 formed as an optoelectronic device. It is understood that similarly numbered and/or named components may function in a substantially similar fashion. Redundant explanation of these components has been omitted for clarity. First semiconductor layer 113 is formed on top of each columnar structure of the plurality of columnar structures 110. More specifically, first semiconductor layer 113 is disposed over buffer layer 112. A second buffer layer 114 can disposed over first semiconductor layer 113, with a further second semiconductor layer 115 disposed thereupon.

Further shown in FIG. 2 is a through-silicon-via 122 with a contact bump 121 for in the substrate 101. The TSV via 122 and contact bump 121 form a negative contact electrode 120. The trenches 102 can be filed with passivating SiO₂ and a positive contact electrode formed thereupon. Other materials such as silicon nitride (SiNx) or alumina (Al₂O₃) can also be used and deposited by a number of deposition techniques to form the passivating film.

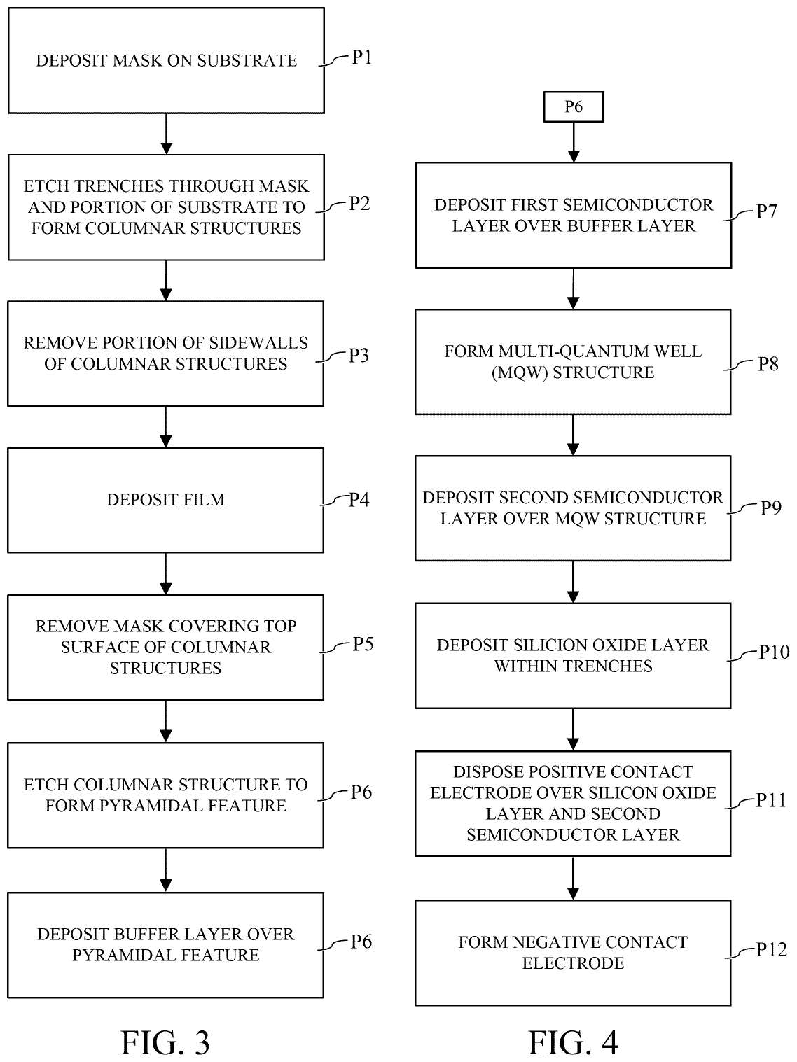

FIGS. 3-4 shows a flowchart illustrating one embodiment of a process for manufacturing an array of optoelectronic devices, with the steps of fabrication expressly delineated therein. A mask is deposited on the substrate, step P1, and then trenches are etched through the mask and portions of the substrate to for columnar structures 110, step P2. Then portions of the vertical sidewalls are removed, step P3, and then a film is deposited, step P4. The mask covering the top surface of the columnar structures 110 is then removed, step P5, and then the columnar structure 130 is etched to form a pyramidal structure 130, step P6, and a buffer layer 112 is deposited over the pyramidal structure 130, step P6.

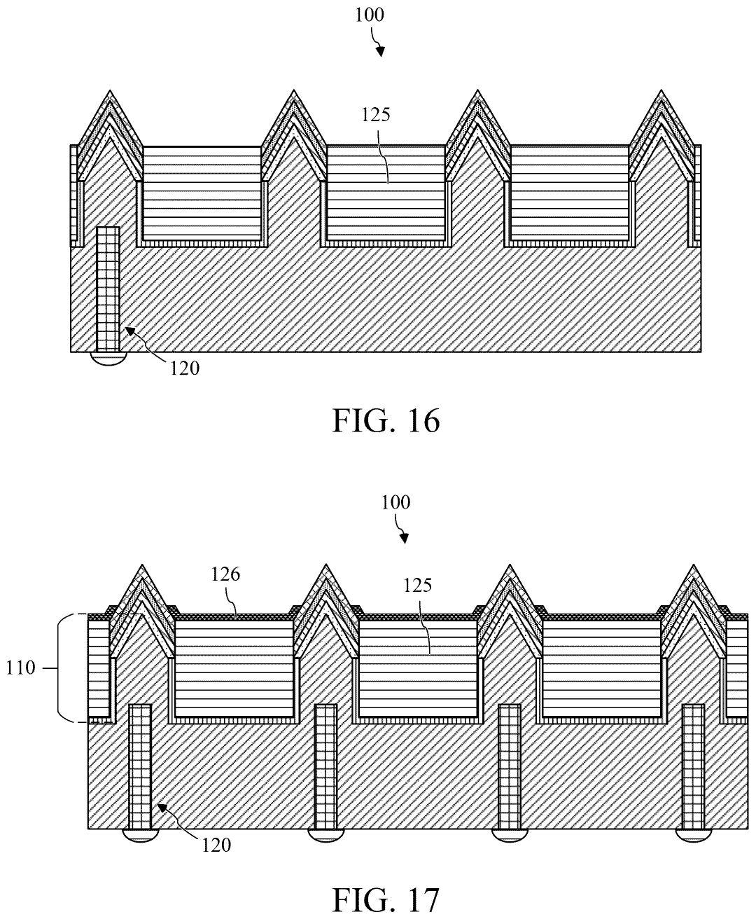

The process then continues with a first semiconductor layer 113 formed over buffer layer 112, step P7, and then a multi-quantum well (MQW) structure (such as shown in FIG. 17) is formed, step P8. A second semiconductor layer 115 can be formed over the MQW structure, step P9, and then a silicon oxide layer 125 (FIG. 16) is deposited within trenches 102, step P10. Then a positive contract electrode 126 (FIG. 17) is disposed over the silicon oxide layer, step P11, and a negative contact electrode 120 is formed, step P12.

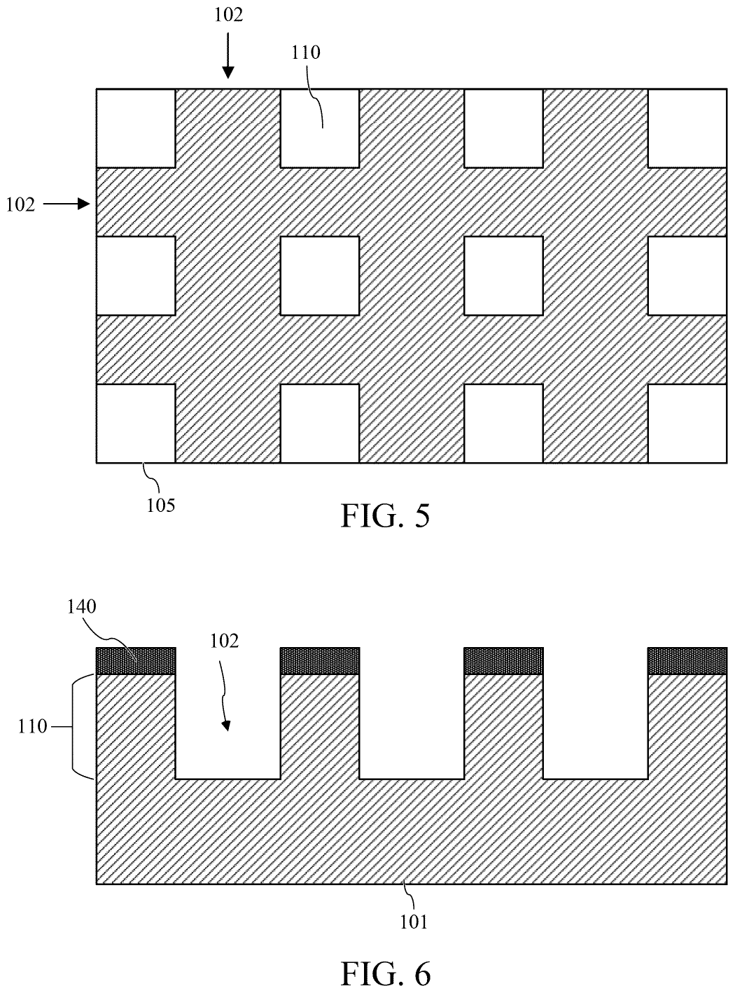

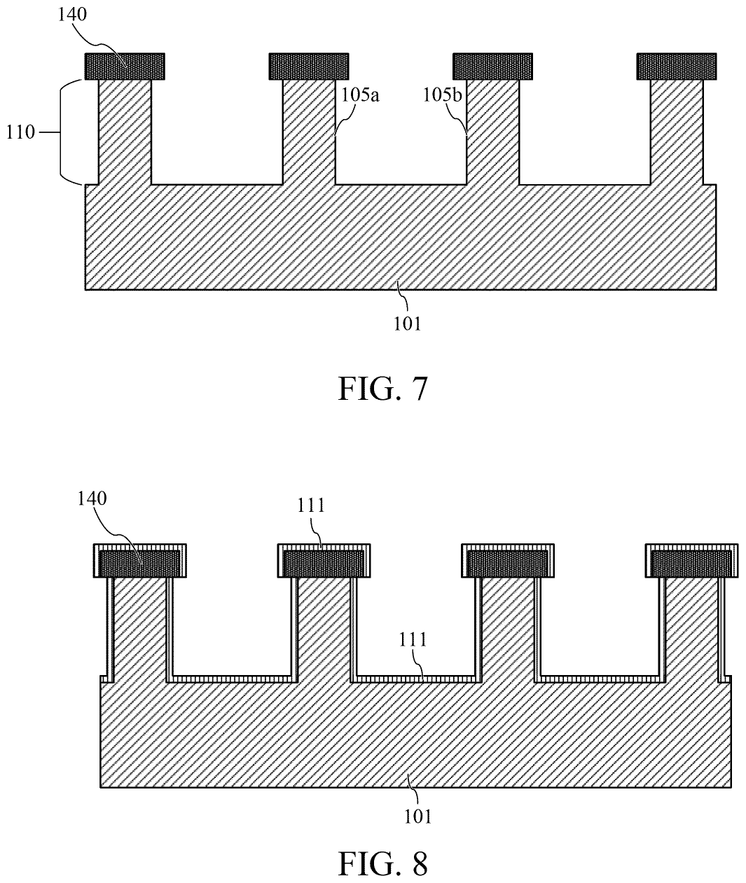

FIG. 5 is a top view of the Si substrate surface 102 after the deposition of the Ti or Cr mask pads 110 with a vertical side wall 105. FIG. 6 is a cross-section view of the columnar structures 110 being etched in the substrate 101 of FIG. 5, creating vertical side walls 105 a,b in FIG. 7.

FIG. 7 is a cross-section of the columnar structures of FIG. 6, illustrating the under etch of the silicon columns 110 under the Ti or Cr pads 140 and the trenches 102 and sidewalls 105 of the columnar structures 110. FIG. 8 is a side cross-sectional view of the deposition of a film 111 of SiO₂ on the under-etched columnar structures 110 and Ti or Cr layer 140 in FIG. 7.

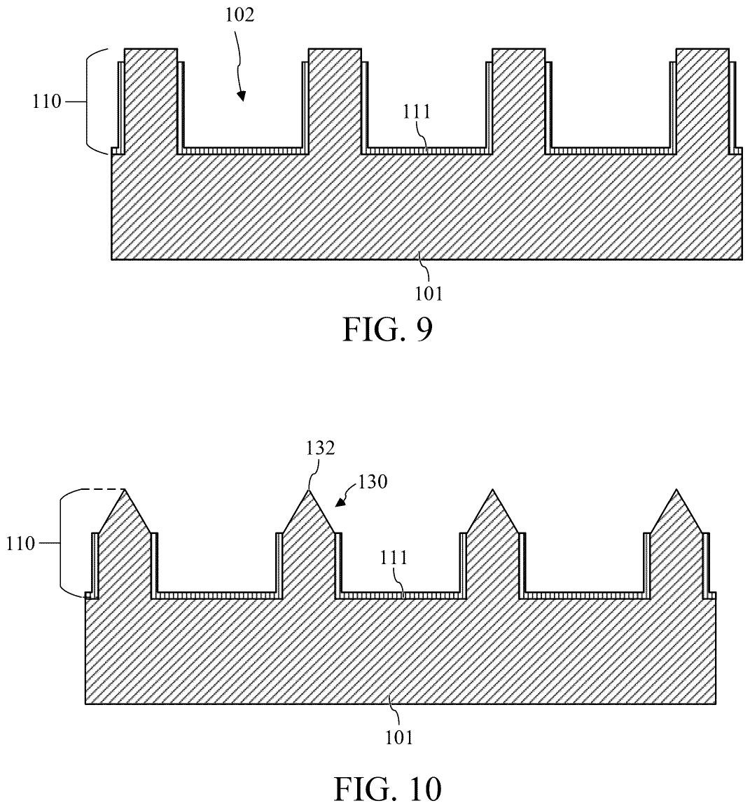

FIG. 9 is a side cross-sectional view of a deposited film 111 on the etched substrate 101 including the trenches 102, here embodied without Ti or CR pads 140. FIG. 10 is a side cross-sectional view of the formation of the pyramidal structures 130 on the columnar structures 110 after the deposition of the film 11 in FIG. 9. The pyramidal structure 130 tapers to a tip 132.

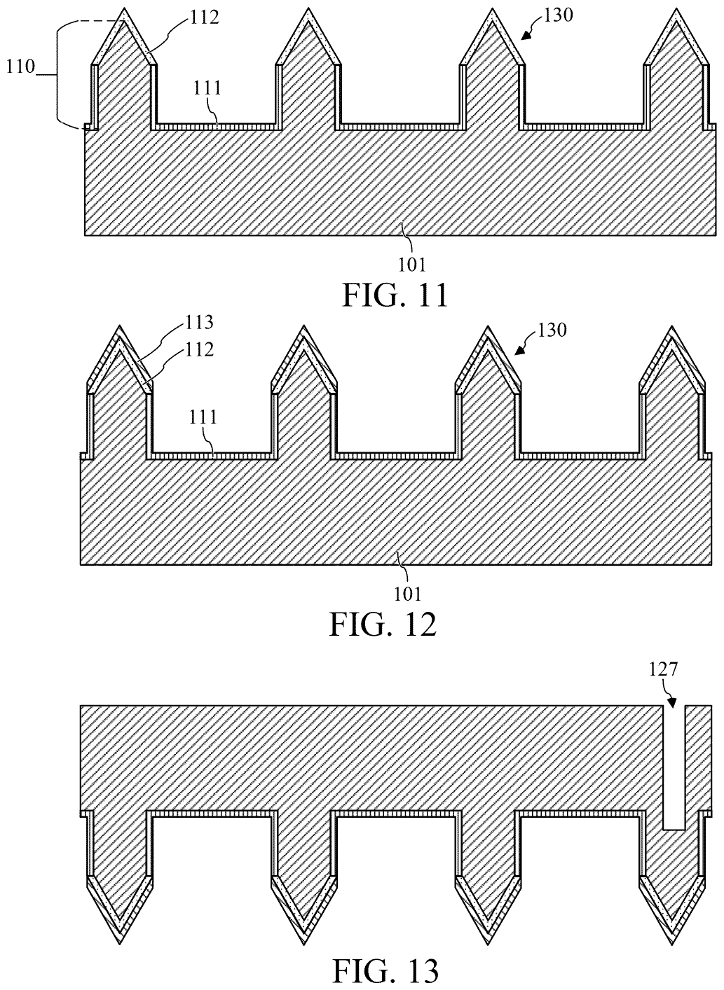

FIG. 11 is a side cross-sectional view of the device of FIG. 10 with a layer 112 of SiGeC deposited on the pyramidal structure 130. FIG. 12 is a side cross-sectional view of the device of FIG. 11 with a layer 113 of InGaN deposited on the layer 112 of SiGeC on the pyramidal structure 130.

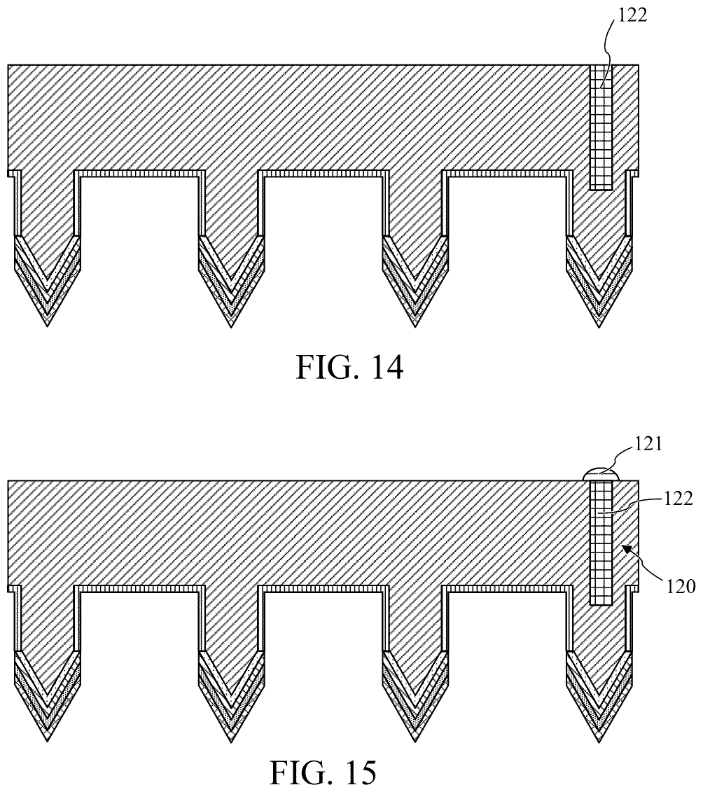

FIG. 13 is a side cross-sectional view of fabricating of a hole 127 for a through-silicon via (TSV) and creation of a negative contact anode 122 as ultimately shown in FIG. 14. TSV are fabricated through photolithography and reactive-ion etching (RIE) and are presented here as a via-last integration approach. However, a via-first integration approach could be used as well, without affecting the overall functionality of the LED array. The crosstalk between the micro-LEDs supported by each of the columnar structures can be successfully suppressed through the deposition of a liner on the walls of the silicon via before the conductive material is placed in the hole. The liner serves to insulate the conductive material from the surrounding silicon and can be either SiO2, SiNx or alumina (Al₃O₃) deposited by PECVD or atomic layer deposition (ALD). Such processes are commonly used and are well known to those skilled in the art.

FIG. 14 is a side cross-sectional view of the device of FIG. 13 with a conductive material placed into the hole 127 to form TSV 122. FIG. 15 is a side cross-sectional view of the device of FIG. 14 with a contact bump 121 adhered to the TSV 122 to create a negative contact electrode 120.

FIG. 16 is a side cross-sectional view of the device of FIG. 15, with a layer 125 of passivating SiO₂ disposed in the trenches 102, filing the sidewalls 102 and touching the top layer of the pyramidal structure 130. FIG. 17 is a side cross-sectional view of the device of FIG. 16, with a conductive layer disposed on the passivating SiO₂ layer 125 to form a positive contact electrode 126. FIG. 17 further illustrates a plurality of multi-quantum well structures.

It is to be understood that similarly numbered and/or named components may function in a substantially similar fashion. Redundant explanation of these components has been omitted for clarity.

The foregoing drawings show some of the processing associated according to several embodiments of this disclosure. In this regard, each drawing or block within a flow diagram of the drawings represents a process associated with embodiments of the method described. It should also be noted that in some alternative implementations, the acts noted in the drawings or blocks may occur out of the order noted in the figure or, for example, may in fact be executed substantially concurrently or in the reverse order, depending upon the act involved. Also, one of ordinary skill in the art will recognize that additional blocks that describe the processing may be added.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A buffer layer in an optoelectronic device, comprising at least:
silicon ranging from 0% to 30%;
carbon ranging from 0% to 10%; and
germanium ranging from 60-99%.

2. The buffer layer of claim 1, wherein carbon ranges from 1% to 7%, and germanium ranges from 93% to 99%.

3. The buffer layer of claim 1, wherein silicon ranges from 1% to 30%, and germanium ranges from 70% to 99%.

4. The buffer layer of claim 1, wherein silicon ranges from 1% to 5%, carbon ranges from 1%-7%, and germanium ranges from 88% to 98%.

5. A method of manufacturing an array of optoelectronic devices, the method comprising:
depositing a mask layer on a substrate;
etching vertical trenches through the mask layer and a portion of the substrate to form a plurality of columnar structures extending from the substrate, each of the plurality of columnar structures including a top surface covered by the mask layer, and a plurality of side walls formed adjacent to the top surface;
removing a portion of the plurality of side walls for each of the plurality of columnar structures to expose a section of the mask layer adjacent the top surface of each of the plurality of columnar structures;
depositing a film within the vertical trenches and over each of the plurality of side walls for each of the plurality of columnar structures, and over at least a portion of the mask layer of each of the plurality of columnar structures and such that at least a portion of the exposed section of the mask layer is uncovered by the deposited film;
removing the mask layer covering the top surface of each of the plurality of columnar structures, including removing the deposited film;
removing at least a portion of the deposited film over each of the plurality of sidewalls for each of the plurality of column structures, the removal adjacent to the top surface thereof to expose an upper portion of each of the plurality of side walls through the deposited film;
etching at least one of:
the top surface of each of the plurality of columnar structures,
the exposed upper portion of each of the plurality of side walls, or
the deposited film to form a pyramidal feature in each of the plurality of columnar structures; and
depositing a buffer layer over the pyramidal feature formed in each of the plurality of columnar structures.

6. The method of claim 5, wherein, the vertical trenches are etched anisotropically.

7. The method of claim 5, wherein the mask layer contains at least one of titanium or chromium.

8. The method of claim 5, wherein the etching includes reactive-ion etching.

9. The method of claim 5, wherein the film contains at least one of: silicon oxide or silicon nitride.

10. The method of claim 5, wherein the deposition is at least one of: chemical vapor deposition or ultrahigh chemical vapor deposition.

11. The method of claim 5, further comprising:
depositing a first semiconductor layer over the buffer layer, the buffer layer deposited on the pyramidal feature in each of the plurality of columnar structures; and
forming a multi-quantum well (MQW) structure by:
depositing a second semiconductor layer over the MQW structure, the second semiconductor layer deposited over the pyramidal feature in each of the plurality of columnar structures;
depositing a silicon oxide layer within the vertical trenches adjacent to and contacting at least one or more of the deposited film, the buffer layer, the first semiconductor layer, the MQW structure, and the second semiconductor layer;
disposing a positive contact electrode over the silicon oxide layer and at least a portion of the second semiconductor layer; and
forming a negative contact electrode.

12. The method of claim 11, wherein the disposing of the positive contact electrode further includes forming the positive contact electrode over at least the portion of the second semiconductor layer such that a tip of the second semiconductor layer is exposed.

13. The method of claim 11, wherein the forming of the negative contact electrode further includes:
forming a through silicon via (TSV) through the substrate and at least partially extending through at least one columnar structure of the plurality of columnar structures; and
forming a contact bump over the TSV.

14. An optoelectronic device, comprising:
a substrate;
a plurality of columnar structures formed from the substrate, each of the plurality of columnar structures having a top surface, a plurality of side walls formed adjacent to the top surface, and a perimeter face thereof;
a plurality of vertical trenches formed adjacent to each of the plurality of columnar structures;
a film disposed over the substrate and alongside the perimeter face of each columnar structure; and
a buffer layer disposed over each columnar structure, wherein the buffer layer is an alloy of germanium.

15. The optoelectronic device of claim 14, further comprising:
an active region disposed over the buffer layer, wherein the active region includes:
a first semiconductor layer (n-type);
a second semiconductor layer (p-type);
a multi-quantum well (MQW) structure formed between the n-type semiconductor layer and the p-type semiconductor layer;
a silicon oxide layer formed within each of the plurality of vertical trenches and contacting:
the film,
the buffer layer,
the first semiconductor layer,
the MQW structure, and
the second semiconductor layer;
a positive contact electrode disposed over the silicon oxide layer and at least a portion of the second semiconductor layer in contact with a p-type semiconductor barrier of the active region and the silicon oxide layer;
a through silicon via (TSV) formed through the substrate and at least partially extending through at least one columnar structure of the plurality of columnar structures; and
a contact bump formed over the TSV.

16. The optoelectronic device of claim 15, wherein the positive contact is formed over at least a portion of the second semiconductor layer such that a tip of the second semiconductor layer is exposed.

17. The optoelectronic device of claim 14, wherein the substrate is at least one of: silicon (Si), silicon carbide (SiC), sapphire (Al2O3), aluminum nitride (AlN), gallium nitride (GaN), or germanium (Ge).

18. The optoelectronic device of claim 14, wherein the substrate is at least one of: poly-crystalline or mono-crystalline.

19. The optoelectronic device of claim 14, wherein each of the plurality of columnar structures contain a pyramidal tip.

20. The optoelectronic device of claim 14, wherein the film is at least one of silicon dioxide or silicon nitride.
